(19) United States
(12) Patent Application Publication
(10) Pub. No.: US 2025/0096520 A1
(43) Pub. Date: Mar. 20, 2025

(54) CYLINDRICAL WHITE LIGHT LASER DIODE PACKAGING STRUCTURE

(71) Applicant: CHING HO HUANG, NEW TAIPEI CITY (TW)

(72) Inventors: CHING HO HUANG, NEW TAIPEI CITY (TW); YUNG PING CHIA, NEW TAIPEI CITY (TW)

(21) Appl. No.: 18/765,481

(22) Filed: Jul. 8, 2024

(30) Foreign Application Priority Data
Sep. 15, 2023 (TW) 112209998

(51) Int. Cl. H01S 5/02212; H01S 5/02315

(52) U.S. Cl. CPC H01S 5/02212; H01S 5/02315

(57) ABSTRACT

An improved cylindrical white laser diode packaging structure in which a blue laser beam is projected by a blue-light laser chip and the blue laser beam with the fluorescent powder of the ceramic fluorescent powder to generate physical excitation characteristics to reflect the white laser beam. Mainly a base with a concave groove in the middle for fixing a ceramic florescent powder, and the base has a seat bar protruding adjacent to the concave groove, and the front of the seat bar is in a vertical plane or an oblique plane for fixing a blue-light laser chip, and a cover body with a light transmissive mouth on the top surface is fixed to the base to form a cylindrical white light laser diode.

### BACKGROUND OF THE INVENTION

### 1. Field of the Invention

The present invention is an improved cylindrical white light laser diode packaging structure, which belongs to the field of cylindrical laser diode packaging structure technology concerning cylindrical laser diodes that can produce white light.

### 2. Description of Related Art

White light is the most demanded light color for illumination, and nowadays, white light from LEDs is widely used for illumination or related products. However, nowadays, only three colors of laser light, namely red, green and blue, are widely used in various products, and white laser light is not popularly used.

The main reason is that the formation of a white laser beam is based on the coupling of red, green, and blue laser light, and there is a certain degree of difficulty in the mass production of a small volume of laser diode packaging structure technology for coupling red, green, and blue laser light projected by a laser chip into a white laser light, and thus it can be seen that the aforesaid white laser diode packaging structure component is relatively complex, difficult to manufacture, and costly, and there are various factors of high power consumption in the use of the white laser diode, which makes it difficult to popularize widely the white laser diode for use in a wide range of products.

In view of the fact that the aforementioned white light laser diode package has a structural component that is too complex, high cost and high power consumption problems that make it impossible to popularize the use of the shortcomings, therefore, the inventor, based on years of experience in the industry, constantly thinking about the way to improve, and after a number of studies and experiments, and finally found a cylindrical white light laser diode package structure, as for the structure of the present invention, the way, the purpose, the efficacy and the spirit of the invention, please refer to the following examples of the implementation of the illustration, you can fully understand the inventor.

### BRIEF SUMMARY OF THE INVENTION

The present invention is an improved cylindrical white laser diode package structure in which a blue-light laser chip projects a blue light laser beam downwardly onto a ceramic florescent powder, with which the florescent powder thereof generates a physical excitation property to reflect a white laser beam. It mainly has a base with a concave groove in the middle for placing a ceramic florescent powder, and the base has a seat bar protruding adjacent to the concave groove, and the front of the seat bar is in a vertical plane or an oblique plane for fixing a blue-light laser chip, and then a cover body with a light transmissive mouth on the top surface is fixed to the base to form a cylindrical white light laser diode.

The blue laser chip, which is fixed on the vertical plane or the oblique plane of the seat bar, projects the blue laser beam vertically downward toward the ceramic florescent powder, or downwardly at an oblique angle toward ceramic florescent powder, and the blue laser beam projected by the blue laser chip to generate physical excitation characteristics with the fluorescent powder of the ceramic fluorescent powder to reflect the white laser beam.

Also, the upper opening of the concave groove is larger than the bottom of the concave groove, and the concave groove can improve the reflection and concentration of the laser beam.

### BRIEF DESCRIPTION OF THE DRAWINGS

The structure and objectives as well as a preferred mode of implementation and essential concepts of the present invention will be best understood by referring to the following detailed description of an illustrative embodiment in conjunction with the accompanying drawings, wherein:

FIG. 1 is a stereoscopic schematic drawing of decomposition and assembly action of Embodiment 1 of an improved cylindrical white light laser diode packaging structure of the present invention;

FIG. 2 is a schematic drawing of a blue-light laser chip projecting vertically downwards the blue laser beam onto the ceramic florescent powder to reflects the white laser beam in Embodiment 1 of the present invention;

FIG. 3 is a stereoscopic schematic drawing of the decomposition and assembly action of Embodiment 2 of the improved cylindrical white light laser diode packaging structure of the present invention;

FIG. 4 is a schematic drawing of a blue-light laser chip projecting the blue laser beam at an oblique angle downwards toward the ceramic florescent powder to reflects the white laser beam in Embodiment 2 of the present invention.

### DETAILED DESCRIPTION OF THE INVENTION

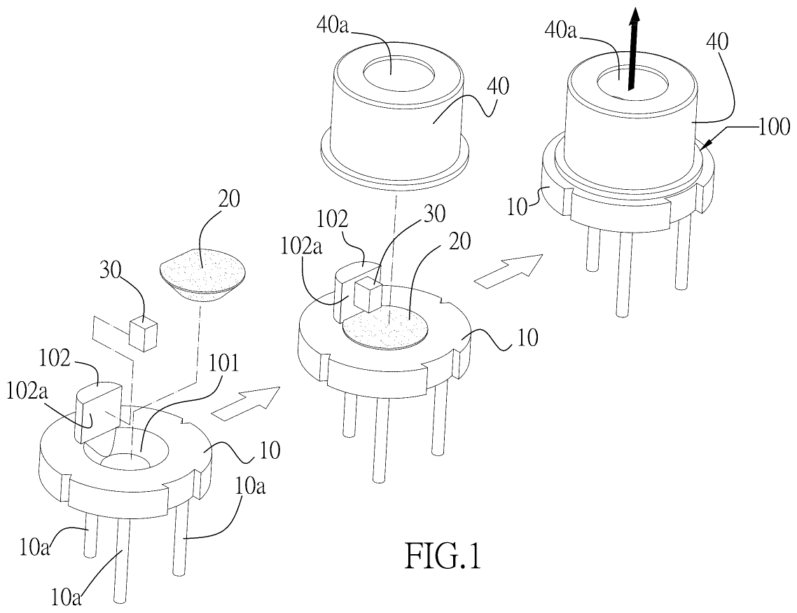

Please refer to FIG. 1 for a stereoscopic schematic drawing of the decomposition and assembly action of Embodiment 1 of an improved cylindrical white light laser diode packaging structure according to the present invention. As shown in the drawing, the base 10 has a concave groove 101 in the middle for fixing a ceramic fluorescent powder 20, and the base 10 has a seat bar 102 protruding adjacent to the concave groove 101, and the front of the seat bar 102 is a vertical plane 102a for fixing a blue-light laser chip 30, and the base 10 has several feet 10a on the bottom surface, and there is also a cap with a light transmittance port 40a on the top surface. The base 10 is provided with several feet 10a on the bottom surface and a cover body 40 with a light transmissive mouth 40a on the top surface is fixed to the base 10 to form a cylindrical white light laser diode 100.

Also, the upper opening of the concave groove 101 is larger than the bottom of the concave groove 101, and the concave groove can improve the reflection and concentration of the laser beam.

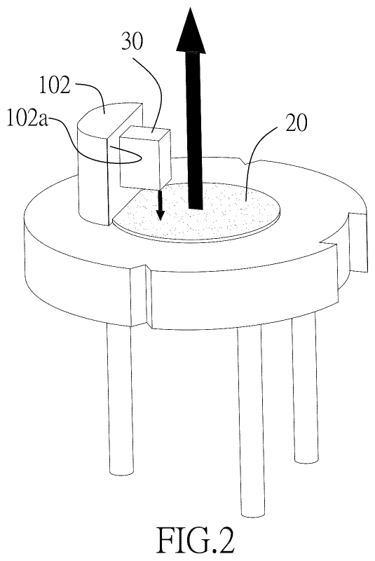

Referring to FIG. 2, a schematic drawing of the blue-light laser chip projecting vertically downwards to project the blue laser beam onto the ceramic fluorescent powder to reflect the white laser beam in Embodiment 1 of the present invention, as shown in the figure, the blue laser beam is projected vertically downwards by the blue-light laser chip 30 which is fixed on the vertical plane 102a of the seat bar 102, then the blue laser beam projects toward the ceramic florescent powder 20 which generated physical excitation characteristics by the fluorescent powder of the ceramic fluorescent powder 20 and the blue laser beam to reflect the white laser beam which is then emitted by the light transmissive mouth 40a of the cover body 40. (see also FIG. 1).

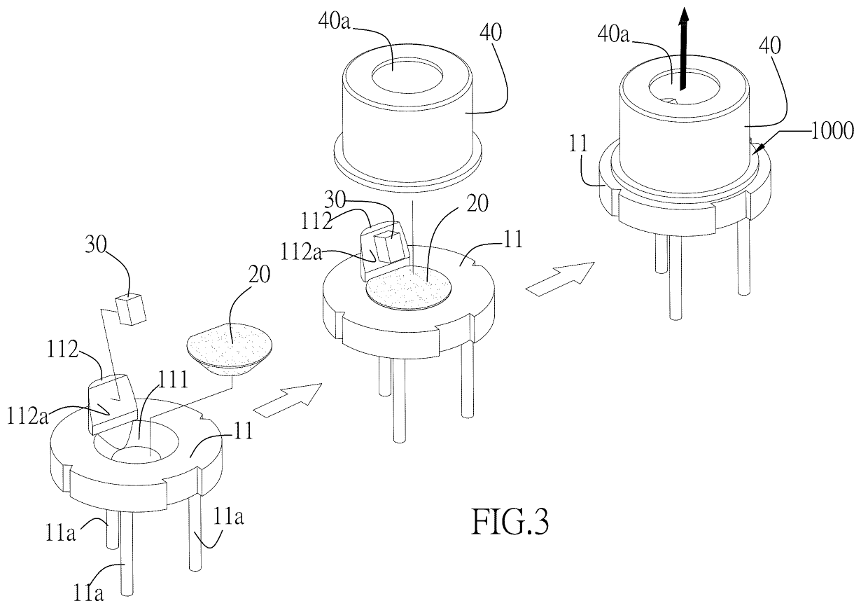

Referring to FIG. 3, a stereoscopic schematic drawing of the decomposition and assembly action of Embodiment 2 of the improved cylindrical white light laser diode packaging structure of the present invention, as shown in the figure, there is a concave groove 111 in the middle of the base 11 for fixing a ceramic fluorescent powder 20, and there is a seat bar 112 protruding from the base 11 adjacent to the concave groove 111 and the front of the seat bar 112 is in an oblique plane 112a for fixing a blue-light laser chip 30, and there are several feet 11a on the bottom surface of the base 11, and there is also a cover body 40 with a light transmissive mouth 40a at the top surface for fixing with the base 11 to form a cylindrical white light laser diode 1000.

Also, the upper opening of the concave groove 111 is larger than the bottom of the concave groove 111, and the concave groove can improve the reflection and concentration of the laser beam.

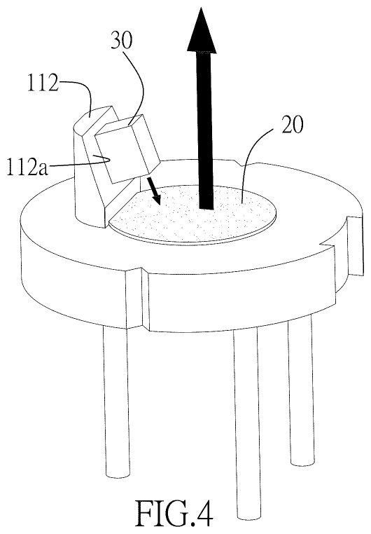

Referring to FIG. 4, a schematic drawing of the blue laser beam projected by the blue-light laser chip at an oblique angle downwards toward the ceramic florescent powder to reflect the white laser beam in Embodiment 2 of the present invention, as shown in the figure, the blue laser beam is projected by the blue-light laser chip 30 which is fixed on the oblique plane 112a of the seat bar 112, then the blue laser beam is projected at an oblique angle downwards towards the ceramic fluorescent powder 20 to generate physical excitation characteristics by the fluorescent powder of the ceramic fluorescent powder 20 and the blue laser beam to reflect the white laser beam which is then emitted by the light transmissive mouth 40a of the cover body 40. (see also FIG. 3).

structure of the present invention is capable of achieving the intended effects. Besides, the present invention has not been put to public use. Therefore, the present invention meets the requirements of utility and novelty for patent application, and an application for patent for the present invention is hereby lawfully filed for examination.

The foregoing is a preferred embodiment of the present invention, and the functions and effects thereof are within the scope of the present invention to the extent that they do not exceed the scope disclosed in the specification and the drawings.

What is claimed is:

1. An improved cylindrical white light laser diode packaging structure, comprising:
a base with a concave groove in the middle for fixing a ceramic fluorescent powder, the base is also provided with a seat bar protruding adjacent to the concave groove, the front of the seat bar is in a vertical plane for fixing a blue-light laser chip, and the base is equipped with several feet on the bottom surface, and a cover body with a light transmissive mouth on the top surface is fixed with the base to form a cylindrical white light laser diode; and
the upper opening of the concave groove is larger than the bottom of the concave groove, and the concave groove can improve the reflection and concentration;
Wherein the blue laser beam is projected by the blue laser chip in the vertical plane of the seat bar, and the blue laser chip projects the blue laser beam vertically downward toward the ceramic florescent powder, with which the florescent powder thereof generates a physical excitation property to reflect a white laser beam, then a white light laser is emitted by the light transmissive mouth of the cover body.

2. An improved cylindrical white light laser diode packaging structure, comprising:
a base with a concave groove in the middle for fixing a ceramic fluorescent powder, the base is also provided with a seat bar protruding adjacent to the concave groove, the front of the seat bar is in an oblique plane for fixing a blue-light laser chip, and the base is equipped with several feet on the bottom surface, and a cover body with a light transmissive mouth on the top surface is fixed with the base to form a cylindrical white light laser diode; and
the upper opening of the concave groove is larger than the bottom of the concave groove, and the concave groove can improve the reflection and concentration;
Wherein the blue laser beam is projected by the blue laser chip in the oblique plane of the seat bar, and the blue laser chip projects the blue laser beam downwardly at an oblique angle toward the ceramic florescent powder, with which the florescent powder thereof generates a physical excitation property to reflect a white laser beam, then a white light laser is emitted by the light transmissive mouth of the cover body.
